(19) United States
(12) Patent Application Publication
(10) Pub. No.: US 2024/0379794 A1
(43) Pub. Date: Nov. 14, 2024

(54) 3DS FET AND METHOD OF MANUFACTURING THE SAME

(71) Applicant: INSTITUTE OF MICROELECTRONICS, CHINESE ACADEMY OF SCIENCES, Beijing (CN)

(72) Inventors: Huaxiang YIN, Beijing (CN); Peng ZHAO, Beijing (CN); Zhenhua WU, Beijing (CN); Jiaxin YAO, Beijing (CN)

(21) Appl. No.: 18/462,613

(22) Filed: Sep. 7, 2023

(30) Foreign Application Priority Data
May 8, 2023 (CN) 202310511961.8

(51) Int. Cl. H01L 29/423; H01L 29/06; H01L 29/66; H01L 29/775; H01L 29/78; H01L 29/786

(52) U.S. Cl. CPC H01L 29/42392; H01L 29/0673; H01L 29/66439; H01L 29/66545; H01L 29/66795; H01L 29/775; H01L 29/785; H01L 29/78696

(57) ABSTRACT

Provided are a three-dimensional stack field-effect transistor (3DS FET) and a method of manufacturing the same. According to embodiments, the 3DS FET includes: a lower active region arranged on a substrate, an upper active region above the lower active region and a gate stack. The lower active region includes: a fin extending in a first direction on the substrate, and lower source/drain portions at two opposite ends of the fin in the first direction, respectively. The upper active region includes: one or more nanosheets, a lowest nanosheet is spaced apart from the fin in a vertical direction relative to the substrate, and upper source/drain portions at two opposite ends of the one or more nanosheets in the first direction, respectively. The gate stack extends in a second direction intersecting with the first direction so as to intersect with the fin and the one or more nanosheets.

### CROSS REFERENCE

This application claims priority of Chinses patent application No. 202310511961.8 filed on May 8, 2023 in China National Intellectual Property Administration, the whole disclosure of which is incorporated herein by reference in its entirety.

### TECHNICAL FIELD

The present disclosure relates to the field of semiconductors, and in particular, to a three-dimensional stack field-effect transistor (3DS FET) and a method of manufacturing the same.

### BACKGROUND

In response to the trend of continuous miniaturization of integrated circuits (IC), various device structures have been proposed to achieve higher integration density and overall performance. For example, the nanosheet (NS) gate-all-around field effect transistor (GAAFET) may replace the fin field effect transistor (FinFET) technology at 3 nm and lower nodes. Furthermore, the three-dimensional stack field effect transistor (3DS FET) or the vertical field effect transistor (VFET) is expected to become the main technology roadmap after the 1 nm node.

At present, there are two main types of processes for implementing 3DS FET, namely, sequential integration (e.g., Sequential 3D) and self-aligned monolithic integration (e.g., Self-Aligned Monolithic 3D). The sequential 3D is simple, but requires two times of processes, resulting in higher costs and upper layer devices facing integration thermal budget constraints. The self-aligned monolithic 3D is highly integrated and is superior in performance, but the process thereof is complex and is not very compatible with existing GAAFET processes, requiring a significant increase in process steps and having a poor controllability.

### SUMMARY

In view of this, an objective of the present disclosure is at least partially to provide a novel three-dimensional stack field effect transistor (3DS FET) and a method of manufacturing the same.

According to an aspect of the present disclosure, a 3DS FET is provided, including: a lower active region arranged on a substrate, the lower active region includes: a fin extending in a first direction on the substrate, and lower source/drain portions at two opposite ends of the fin in the first direction, respectively; an upper active region arranged above the lower active region, the upper active region includes: one or more nanosheets, a lowest nanosheet is spaced apart from the fin in a vertical direction relative to the substrate, and upper source/drain portions at two opposite ends of the one or more nanosheets in the first direction, respectively; and a gate stack extending in a second direction intersecting with the first direction so as to intersect with the fin and the one or more nanosheets.

According to another aspect of the present disclosure, there is provided a method of manufacturing a 3DS FET, including: providing a stack of a sacrificial layer and a nanosheet alternating with each other on a substrate; patterning the stack and an upper portion of the substrate into a stripe shape extending in a first direction, the patterned upper portion of the substrate forms a fin; thinning the fin to reduce a width of the fin in a second direction intersecting with the first direction; forming an isolation layer on the substrate, the isolation layer covers the fin; etching the isolation layer downwardly to expose an upper portion of the fin; forming a dummy gate on the isolation layer; etching the stack and the fin based on the dummy gate; forming lower source/drain portions at two opposite ends of the fin in the first direction; forming an source/drain inter isolation layer on the lower source/drain portions; forming upper source/drain portions at two opposite ends of the nanosheet in the first direction; and replacing the dummy gate with a gate stack.

According to another aspect of the present disclosure, there is provided an electronic apparatus, including the 3DS FET described above.

According to embodiments of the present disclosure, a novel 3DS FET and a method of manufacturing the same are proposed. According to embodiments of the present disclosure, in the manufacturing process of the gate-all-around field effect transistor (GAAFET), through partial process modifications, a lower fin field-effect transistor (FinFET) device is formed in situ using a sub-fin region, and a highly integrated 3DS FET is formed together with an upper GAAFET device, so that the complexity of the manufacturing process may be greatly reduced, and the controllability may be greatly increased.

### BRIEF DESCRIPTION OF THE DRAWINGS

The above and other objectives, features and advantages of the present disclosure will be more apparent through the following descriptions of embodiments of the present disclosure with reference to the accompanying drawings, in which:

FIGS. 1(a) to 1(d) schematically show local decomposition perspective views of a 3DS FET according to embodiments of the present disclosure;

FIG. 2(a) to FIG. 20(c) schematically show some stages in a process of manufacturing a 3DS FET according to embodiments of the present disclosure.

Throughout the accompanying drawings, the same or similar reference numerals indicate the same or similar components.

### DETAILED DESCRIPTION OF EMBODIMENTS

Embodiments of the present disclosure will be described below with reference to the accompanying drawings. However, it should be understood that these descriptions are merely exemplary and are not intended to limit the scope of the present disclosure. In addition, in the following descriptions, descriptions of well-known structures and technologies are omitted to avoid unnecessarily obscuring the concept of the present disclosure.

Various schematic structural diagrams according to embodiments of the present disclosure are shown in the accompanying drawings. The drawings are not drawn to scale. Some details are enlarged and some details may be omitted for clarity of presentation. Shapes of various regions and layers as well as relative sizes and positional relationships thereof as shown in the drawings are only exemplary. In practice, there may be deviations due to manufacturing tolerances or technical limitations, and those skilled in the art may additionally design regions/layers with different shapes, sizes, and relative positions according to actual requirements.

In the context of the present disclosure, when a layer/element is referred to as being “on” another layer/element, the layer/element may be directly on the another layer/element, or there may be an intermediate layer/element between them. In addition, if a layer/element is located “on” another layer/element in one orientation, the layer/element may be located “under” the further layer/element when the orientation is reversed.

The present disclosure may be presented in various forms, some examples of which will be described below. In the following descriptions, a selection of various materials is involved. In the selection of materials, in addition to a function of the material (for example, a semiconductor material may be used to form an active region, and a dielectric material may be used to form an electrical isolation), etching selectivity is also considered. In the following descriptions, required etching selectivity may or may not be indicated. It should be clear to those skilled in the art that when etching a certain material layer is mentioned below, if it is not mentioned or shown that other layers are also etched, then the etching may be selective, and the material layer may have etching selectivity relative to other layers exposed to the same etching recipe.

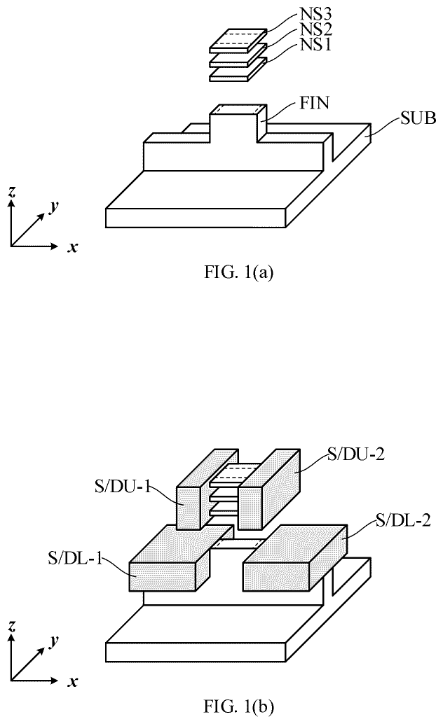

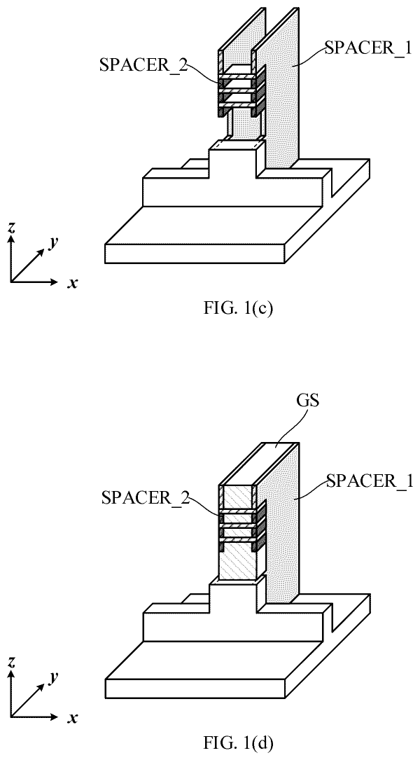

FIG. 1(a) to FIG. 1(d) schematically show local decomposition perspective views of a 3DS FET according to embodiments of the present disclosure.

FIG. 1(a) schematically shows a channel portion of a 3DS FET according to an embodiment. The 3DS FET may be arranged on a substrate SUB. The 3DS FET includes a lower layer device (such as FinFET) and an upper layer device (such as GAAFET) stacked vertically on each other on the substrate SUB. FIG. 1(a) shows a lower channel portion FIN for the lower layer device and an upper channel portion (NS1, NS2, NS3) for the upper layer device.

The lower channel FIN may have a fin shape that extends in a first direction (e.g., x-direction). Lower source/drain portions (see S/DL-1 and S/DL-2 as shown in FIG. 1(b)) may be formed at two opposite ends of the lower channel FIN in the first direction (e.g., x-direction).

The upper channel portion may include nanosheets NS1, NS2, and NS3, each of which may extend in a direction substantially parallel to an upper surface of the substrate SUB and have a length in the first direction (e.g., x-direction) and a width in a second direction (e.g., y-direction) that intersects with (e.g., perpendicular to) the first direction. According to the width in the second direction, nanosheets NS1, NS2, and NS3 may also be formed as nanowires. Upper source/drain portions (see S/Du-1 and S/Du-2 as shown in FIG. 1(b)) may be formed at two opposite ends of the upper channel portion in the first direction (e.g., x-direction).

Here, the upper channel portion is shown as including three semiconductor nanosheets NS1, NS2, and NS3, however, the present disclosure is not limited to this. For example, the upper channel portion may include more or fewer nanosheets.

The upper channel portion and the lower channel portion may be spaced apart in a vertical direction (e.g., z-direction) and may be self-aligned with each other, particularly substantially centrally aligned (e.g., z-direction). The nanosheets NS1, NS2, and NS3 in the upper channel portion may be spaced apart in the vertical direction (e.g., z-direction) and may be self-aligned with each other. This will be further described in detail below.

A length of the lower channel portion in the first direction (e.g., x-direction) may be greater than a length of the upper channel portion in the first direction (e.g., x-direction). As shown by a dashed line in FIG. 1(a), the lower channel portion may include an elongated portion protruding relative to the upper channel portion in the first direction (e.g., x-direction). For example, such elongated portion may correspond to a second spacer as described below. In addition, a width of the upper channel portion in the second direction (e.g., y-direction) may be greater than a width of the lower channel portion in the second direction (e.g., y-direction). As shown by a dashed line in FIG. 1(a), the upper channel portion may include an elongated portion protruding relative to the lower channel portion in the second direction (e.g., y-direction). For example, such elongated portion is caused by a process of thinning the lower channel portion to form a thin fin.

FIG. 1(b) schematically shows source/drain portions of a 3DS FET according to an embodiment. More specifically, the lower layer device may include lower source/drain portions S/DL-1 and S/DL-2 (together with the lower channel portion to form an active region of the lower layer device, also referred to as a lower active region) formed at two opposite ends of the lower channel portion, and the upper layer device may include upper source/drain portions S/Du-1 and S/Du-2 (together with the upper channel portion to form an active region of the upper layer device, also referred to as an upper active region) formed at two opposite ends of the upper channel portion. In a case that the upper channel portion includes separate nanosheets NS1, NS2, and NS3, the upper source/drain portion S/Du-1 may connect one end of each nanosheet in the first direction to each other, and the upper source/drain portion S/Du-2 may connect the other end of each nanosheet in the first direction to each other.

In order to facilitate a formation of contact plugs to the lower source/drain portions S/DL-1 and S/DL-2 of the lower layer device, the lower source/drain portions S/DL-1 and S/DL-2 may respectively protrude relative to the upper source/drain portions S/Du-1 and S/Du-2 in at least one of the first direction (e.g., x-direction) and the second direction (e.g., y-direction), and then the contact plugs may be landed onto the protrusion.

FIG. 1(c) schematically shows a spacer structure of a 3DS FET according to an embodiment. In FIG. 1(c), for clarity, each nanosheet in the upper channel portion is cut in the middle in the first direction (e.g., x-direction), and the spacer structure is correspondingly cut (a cross-section of a cut portion is indicated by oblique lines).

As shown in FIG. 1(c), the spacer structure may include an outer spacer SPACER_1 and an inner spacer SPACER_2. The spacer structure may extend in the second direction (e.g., y-direction) and define a space for a gate stack. End portions of the lower channel portion and (each nanosheet in) the upper channel portion in the first direction (e.g., x-direction) may be exposed from the spacer structure (connected to corresponding source/drain portions).

A sidewall of (each nanosheet in) the upper channel portion extending in the second direction (e.g., y-direction) may be self-aligned, e.g., substantially coplanar, with a sidewall of the outer spacer SPACER_1; while a sidewall of the lower channel portion extending in the second direction (e.g., y-direction) may protrude relative to the sidewall of the outer spacer SPACER_1 in the first direction.

When viewing in the first direction (e.g., x-direction), the outer spacer SPACER_1 may have an opening, the opening having: a first edge extending along an upper surface of the uppermost nanosheet (NS3) in the upper channel portion; a second edge and a third edge (only one of which may be seen in FIG. 1(c) for cutting reasons) respectively extending along side surfaces of two opposite sides of each nanosheet in the second direction (e.g., y-direction), the second edge and the third edge respectively extend vertically downward (e.g., in z-direction) from two opposite sides of the first edge in the second direction (e.g., in y-direction) up to near a top surface of the lower channel portion FIN; and a fourth edge and a fifth edge (only one of which may be seen in FIG. 1(c) for cutting reasons) respectively extending from the second edge and the third edge toward the lower channel portion FIN.

The inner spacer SPACER_2 is formed between the nanosheets in the upper channel portion and between the lowest nanosheet (NS1) and the lower channel portion. The inner spacer SPACER_2 may be self-aligned, e.g., substantially coplanar, with the outer spacer SPACER_1. The sidewall of the inner spacer SPACER_2 extending in the second direction (e.g., y-direction) may be substantially coplanar with the sidewall of the outer spacer SPACER_1 (and the sidewall of each nanosheet in the upper channel portion).

When viewing in the first direction (e.g., x-direction), the inner spacer SPACER_2 may extend between adjacent nanosheets in the vertical direction and between the second and third edges of the outer spacer SPACER_1 in the second direction. The inner spacer SPACER_2 may also extend between the second and third edges of the outer spacer SPACER_1 on a lower surface of the lowest nanosheet (NS1).

It can be seen that, the inner spacer SPACER_2 closes a part of the opening of the outer spacer SPACER_1 between the nanosheets. In FIG. 1(c), the opening of the outer spacer SPACER_1 has another part, more specifically, a part in an open state between the lowest nanosheet (NS1) and the lower channel portion FIN, and the part may be filled with a source/drain inter isolation layer between the upper source/drain portion and the lower source/drain portion. Therefore, a gate stack formed on an inner side of the spacer structure and the source/drain portion formed on an outer side of the spacer structure may be reliably electrically isolated from each other. This will be further described in detail below.

Here, the outer spacer SPACER_1 and the inner spacer SPACER_2 are shown in different grayscales. This is because they may be formed in different process steps. As described below, the outer spacer SPACER_1 and the outer spacer SPACER_2 may contain substantially the same material.

FIG. 1(d) schematically shows a gate stack of a 3DS FET according to an embodiment. Similar to FIG. 1(c), in FIG. 1(d), each nanosheet in the upper channel portion is cut in the middle in the first direction (e.g., x-direction) for clarity, and the spacer structure and the gate stack are correspondingly cut (the cross-section of the cut portion is indicated by oblique lines).

As shown in FIG. 1(d), a gate stack GS may be formed within a space defined by spacer structures. The gate stack GS may include a gate dielectric layer and a gate conductor layer (in FIG. 1(d), a stack structure of the gate stack is not shown for convenience). The gate stack GS may extend on upper and lower surfaces of each nanosheet in the upper channel portion, and may also extend on side surfaces of two opposite sides of each nanosheet in the second direction (e.g., y-direction), so as to form a gate-all-around structure and constitute the GAAFET together with the upper channel portion and the upper source/drain portion. In addition, the gate stack GS may extend on the top surface of the lower channel portion FIN and on two opposite sides of the lower channel portion FIN in the second direction (e.g., y-direction), so as to constitute the FinFET together with the lower channel portion FIN and the lower source/drain portion. The FinFET and the GAAFET are stacked in the vertical direction (e.g., z-direction), and may have respective source/drain portions and a common gate stack.

In perspective views of FIG. 1(a) to FIG. 1(d), only main components of the 3DS FET are shown, and other components such as an isolation layer, a gap filling layer, and the like are not shown. According to the present disclosure, other components in the 3DS FET may be apparent to those skilled in the art.

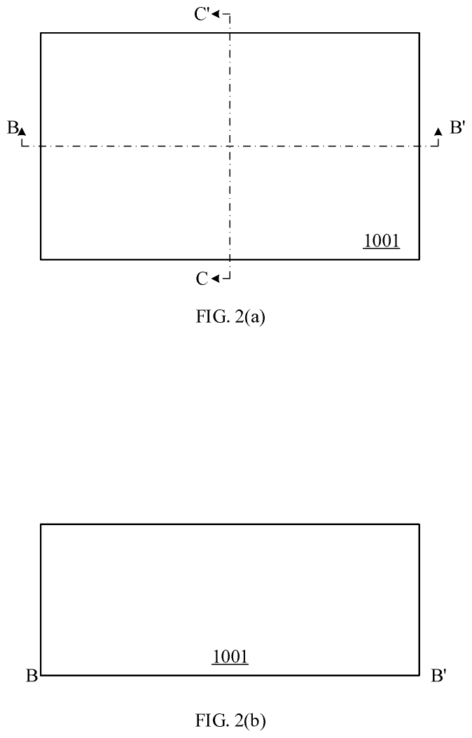

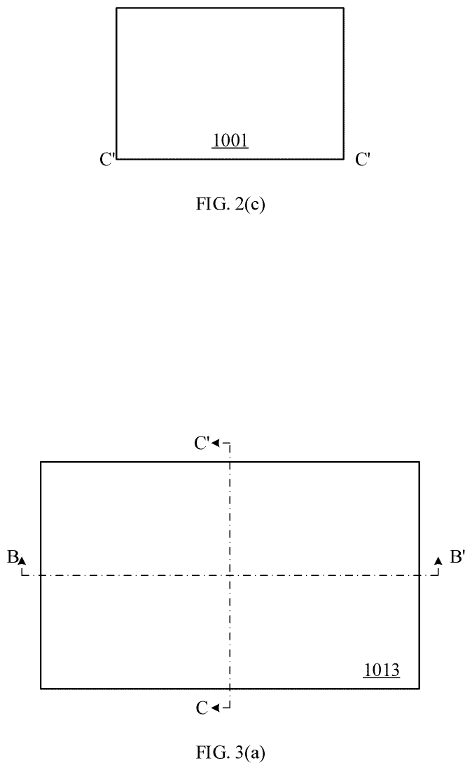

FIG. 2(a) to FIG. 20(c) schematically show some stages in a process of manufacturing a 3DS FET according to embodiments of the present disclosure.

As shown in FIG. 2(a) to FIG. 2(c), a substrate 1001 is provided. The substrate 1001 may be a substrate of various forms, including but not limited to a bulk semiconductor material substrate such as a bulk Si substrate, a semiconductor-on-insulator (SOI) substrate, a compound semiconductor substrate such as a SiGe substrate, and the like. In the following descriptions, for ease of explanation, the bulk Si substrate is illustrated by way of example. Here, a silicon wafer is provided as the substrate 1001.

A well region may be formed in the substrate 1001, a doping type of the well region may be determined based on a conductive type of the device to be formed on the substrate 1001, especially the lower layer device. For example, if a p-type device is to be formed, the well region may be an n-type well; and if an n-type device is to be formed, the well region may be a p-type well. The well region may be formed, for example, by injecting a corresponding conductive type dopant (p-type dopant such as B or In, or n-type dopant such as As or P) into the substrate 1001 and subsequently performing thermal annealing. There are a plurality of ways in the art to set up such well region, which will not be described in detail here.

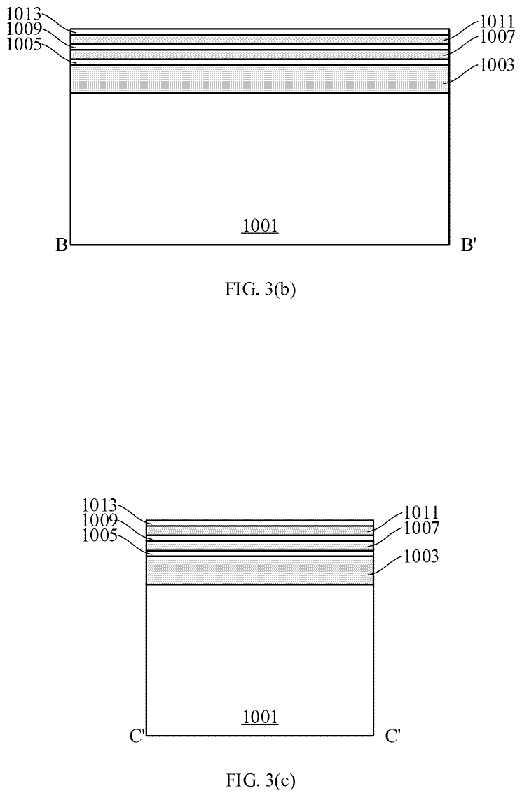

As shown in FIG. 3(a) to FIG. 3(c), a first sacrificial layer 1003, a first nanosheet layer 1005, a second sacrificial layer 1007, a second nanosheet layer 1009, a third sacrificial layer 1011, and a third nanosheet layer 1013 may be sequentially formed on the substrate 1001 through, for example, epitaxial growth. The sacrificial layers and the nanosheet layers may be alternately stacked on the substrate 1001, and may have etching selectivity relative to each other. For example, the sacrificial layer may contain SiGe (for example, an atomic percentage of Ge is about 10% to 50%, preferably about 30% to 35%), while the nanosheet layer may contain Si. The nanosheet layer may be relatively thin, for example, with a thickness of about 1 nm to 40 nm, preferably about 6 nm to 12 nm. The lowermost first sacrificial layer 1003 may be relatively thick, for example, with a thickness of about 2 nm to 100 nm, preferably about 30 nm to 50 nm, so as to define a spacing between the lower layer device and the upper layer device. Thicknesses of other sacrificial layers may be, for example, about 1 nm to 50 nm, preferably about 8 nm to 15 nm, so as to define a spacing between adjacent nanosheets in the upper layer device.

Here, taking a formation of three nanosheets as an example, three nanosheet layers are correspondingly formed. However, the present disclosure is not limited to this. For example, fewer or more nanosheet layers (and correspondingly, more or fewer sacrificial layers alternately stacked therewith) may be formed.

Next, a fin may be patterned. When patterning the fin, in order to better control a thickness of the fin, a spacer pattern transfer (SIT) process may be adopted.

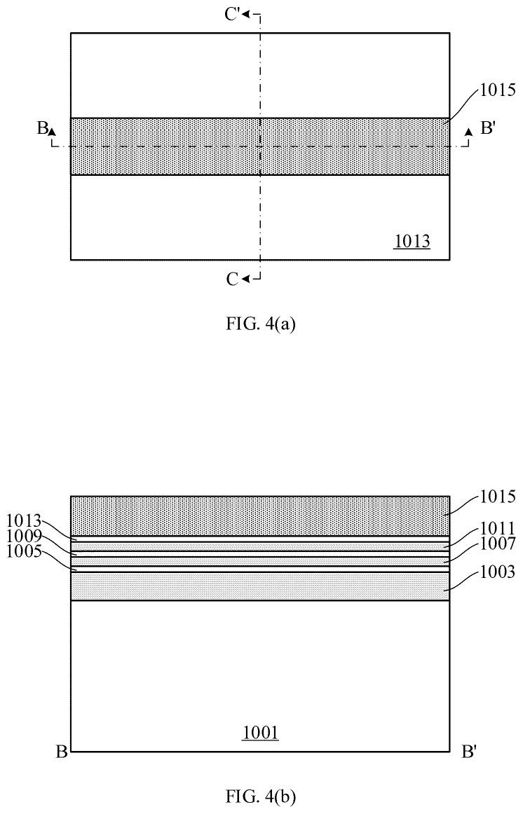

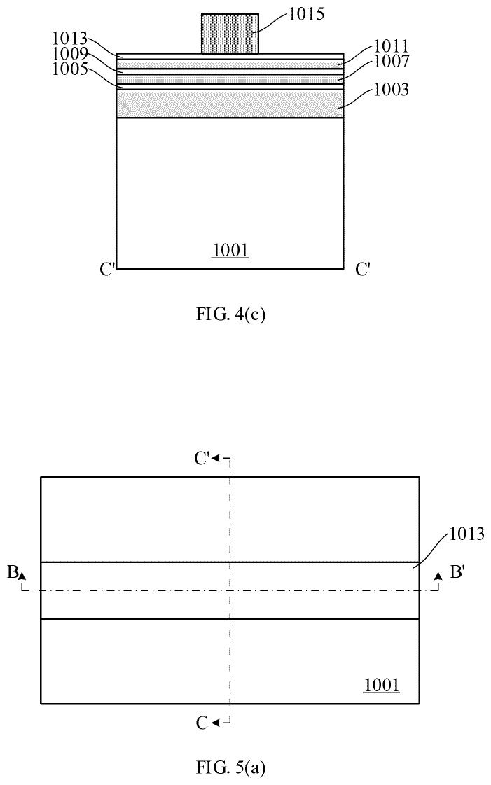

For example, as shown in FIG. 4(a) to FIG. 4(c), a spacer 1015 may be formed on the third nanosheet layer 1013 through a spacer formation process. A mandrel may be formed in the spacer formation process, and then a spacer material layer is deposited in a substantially conformal manner, and anisotropic etching such as vertical reactive-ion etching (RIE) is performed on the spacer material layer, thus the spacer material layer may be left on a sidewall of the mandrel to form the spacer. After that, the mandrel may be removed. The spacer 1015 formed in this way may extend, for example, in the first direction (for example, a horizontal direction in a paper plane in FIG. 4(a) and FIG. 4(b), and a direction perpendicular to a paper plane in FIG. 4(c)). Considering etching selectivity in subsequent processes, the spacer 1015 may contain a nitride, an oxide, a carbide, an organic compound or a combination thereof, such as SiCOₓ, a-C, SOG (Spin On Glass).

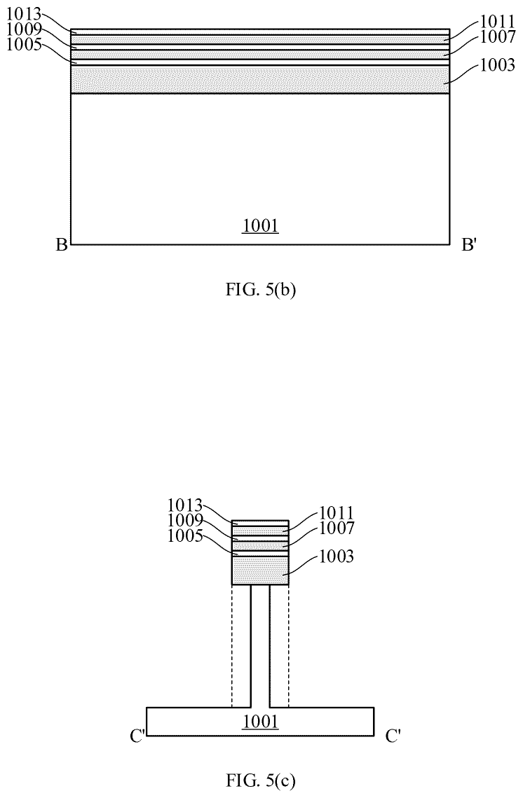

As shown in FIG. 5(a) to FIG. 5(c), the spacer 1015 may be used as an etching mask to perform anisotropic etching, such as the vertical RIE, on lower nanosheet layers and sacrificial layers to transfer a pattern of the spacer 1015 to lower layers. Here, the etching may proceed into the substrate 1001. Therefore, an upper portion of the substrate 1001, and nanosheet layers and sacrificial layers above the upper portion of the substrate 1001, may form a stripe shape that protrude relative to the substrate 1001 and extend in the first direction, as shown in FIG. 5(c). A dashed line in FIG. 5(c) shows a contour after etching using the spacer 1015 as the mask.

In the following descriptions, a protruding portion of the substrate 1001 is referred to as a “fin” (the lower layer FinFET is formed subsequently based on the fin) for convenience.

In order to improve performance of the lower layer device, the fin may be thinned. For example, a thickness of the fin in the second direction (such as a horizontal direction within a paper plane in FIG. 5(c), a vertical direction within a paper plane in FIG. 5(a), and a direction perpendicular to a paper plane in FIG. 5(b)) may be reduced by selective lateral etching for the substrate 1001 (Si). For example, the thickness of the thinned fin in the second direction may be about 1 nm to 50 nm.

Here, an etchant etches the fin from two opposite sides in the second direction, and etching conditions on the two sides are substantially the same, thus an etching amount may also be substantially the same. Therefore, the fin may remain self-aligned with the nanosheet layer above, or remain substantially centrally aligned with the nanosheet layer above.

In addition, in the example, the nanosheet layer contains the same material (Si) as the fin. In this case, in order to protect the nanosheet layer during a thinning treatment of the fin, a process may be performed as follows. For example, the anisotropic etching using the spacer 1015 as the mask may first stop at the top surface of substrate 1001. The etched sacrificial layers and nanosheet layers may be subjected to surface plasma thin layer oxidation or nitridation to form a thin layer of oxide or nitride on sidewalls thereof, followed by further etching and thinning of the substrate 1001 below. Alternatively, the anisotropic etching using the spacer 1015 as the mask may first stop at the top surface of the substrate 1001, a temporary protective spacer may be formed on the top surface of substrate 1001, and then the substrate 1001 below may be etched and thinned. Such thin layer oxide or nitride or the temporary protective spacer may protect the nanosheet during the thinning treatment, and may be removed after the thinning treatment by selective etching.

After that, the spacer 1005 may be removed.

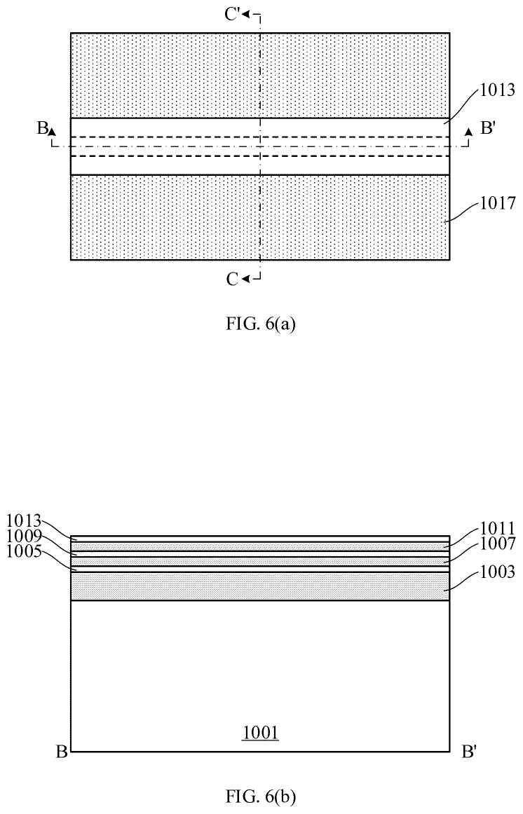

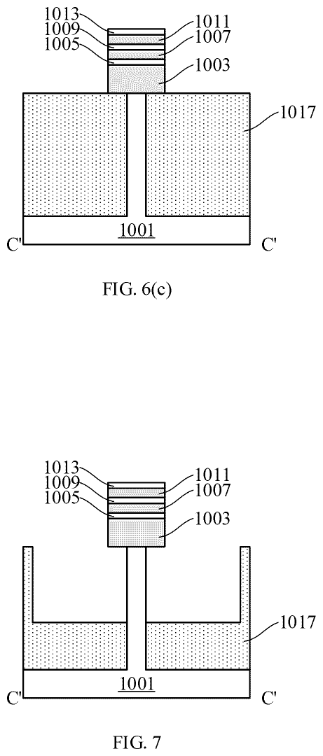

Trenches are formed on two sides of the fin in the substrate 1001. Isolation such as shallow trench isolation (STI) may be formed in such trenches. For example, as shown in FIG. 6(a) to FIG. 6(c), an isolation layer 1017 may be formed by depositing an oxide, performing planarization such as chemical mechanical polishing (CMP) on the deposited oxide, and etching back, e.g., RIE, the planarized oxide. Here, a top surface of the isolation layer 1017 may be near the top surface of the substrate 1001.

As shown in FIG. 6(c), the fin may be surrounded by the isolation layer 1017. In a conventional GAAFET process, the GAAFET is mainly made based on the nanosheet layer above, thus the fin surrounded by the isolation layer 1017 may be considered as a sub-fin region. According to embodiments of the present disclosure, the FinFET may be made based on the sub-fin region.

As shown in FIG. 7, for example, a photoresist is formed, the photoresist is patterned to have an opening extending in the first direction, and the isolation layer 1017 is selectively etched using the patterned photoresist as an etching mask, so as to form a groove extending in the first direction (a direction perpendicular to a paper plane in FIG. 7) in the isolation layer 1017, and the groove may expose an upper portion of the fin. For example, the groove may have a width of about 3 nm to 20 μm in the second direction and a depth (relative to the top surface of the isolation layer 1017) of about 3 nm to 500 nm.

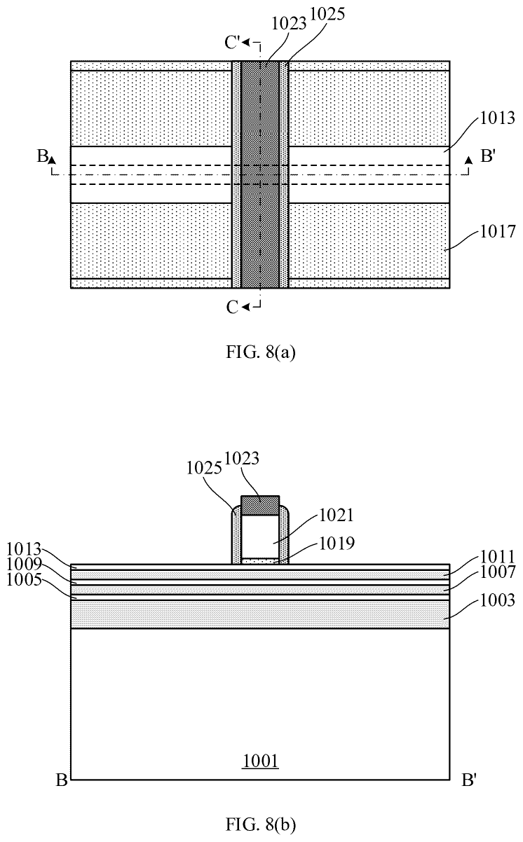

A dummy gate may be formed on the isolation layer 1017. For example, as shown in FIG. 8(a) to FIG. 8(c), a dummy gate dielectric layer 1019 and a dummy gate conductor layer 1021 may be sequentially formed by, for example, deposition. The dummy gate dielectric layer 1019 may be formed in a substantially conformal manner. For example, the dummy gate dielectric layer 1019 may contain an oxide with a thickness of about 0.5 nm to 20 nm, preferably about 0.7 nm to 1.2 nm. For example, the dummy gate conductor layer 1029 may contain polycrystalline silicon. The dummy gate conductor layer 1029 may be planarized, such as CMP, to have a substantially planarized top surface. A hard mask layer 1023 may be formed by deposition on the dummy gate conductor layer 1021. The hard mask layer 1023 may contain a nitride, a carbide, an oxide, an organic compound, an amorphous silicon, a polycrystalline silicon, or a combination thereof, such as a stack structure of dielectric antireflective coating (DARC)/a-Si/SiNₓ/SiuO₂, with a thickness of about 3 nm to 1000 nm, preferably about 30 nm to 100 nm. The hard mask layer 1023, along with the dummy gate conductor layer 1021 and the dummy gate dielectric layer 1019 below, may be patterned together by photolithography into a stripe shape extending in the second direction (e.g., a vertical direction within a paper plane in FIG. 8(a), a direction perpendicular to a paper plane in FIG. 8(b), and a horizontal direction within a paper plane in FIG. 8(c)). A first spacer 1025 may be formed on sidewalls on two opposite sides of the strip shape in the first direction (e.g., the horizontal direction within the paper plane in FIG. 8(a) and FIG. 8(b)). For example, the first spacer 1025 may contain a nitride, a carbide, an oxide, an organic compound, or a combination thereof, such as SiNₓ or SiCOₓ, with a thickness of about 1 nm to 70 nm, preferably about 5 nm to 15 nm. The first spacer 1025 may correspond to the outer spacer as described above.

Although not shown in the drawings, the first spacer 1025 may also be formed on the sidewall of the fin.

A position of a channel portion may be defined based on the dummy gate.

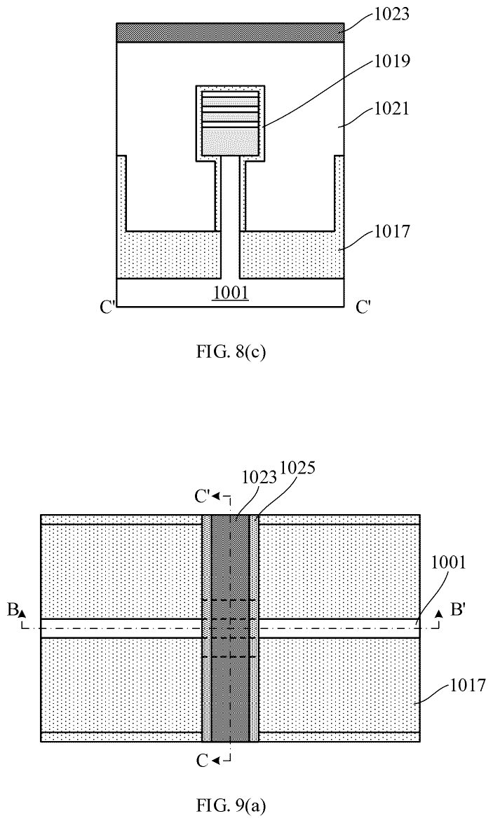

For example, as shown in FIG. 9(a) to FIG. 9(c), the nanosheet layers and the sacrificial layers may be selectively etched by using the hard mask layer 1023 and the first spacer 1025 as an etching mask by anisotropic etching such as vertical RIE. The etching may stop at a top surface of the fin. Thus, the sacrificial layers and the nanosheet layers form a stack located below the dummy gate, and the nanosheet layers in the stack are in the form of nanosheets and may constitute the upper channel portion of the upper layer device.

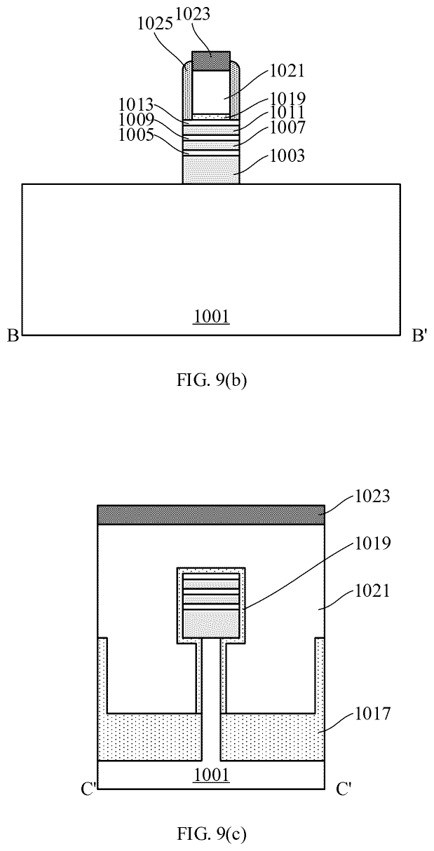

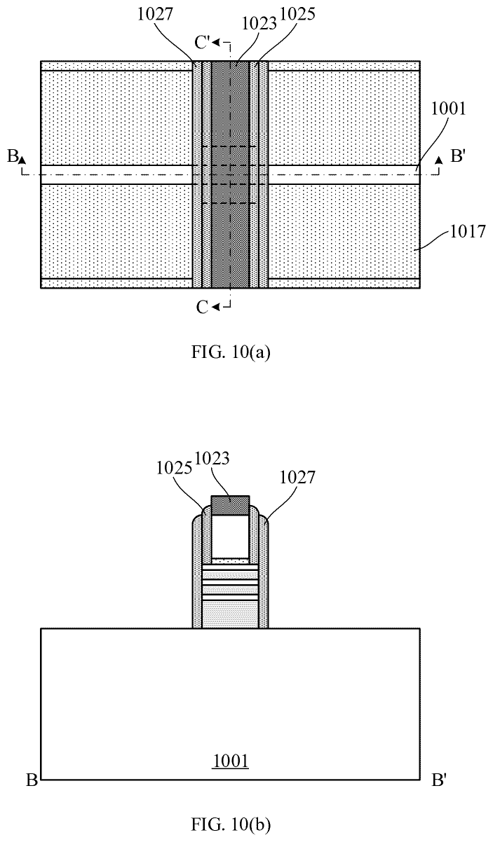

As shown in FIG. 10(a) and FIG. 10(b), a second spacer 1027 may be formed on the sidewall of the first spacer 1025. For example, the second spacer 1027 may contain a nitride, a carbide, an oxide, an organic compound or a combination thereof, such as SiNₓ or SiCOₓ, with a thickness of about 1 nm to 70 nm, preferably about 5 nm to 15 nm. The second spacer 1027 may cover sidewalls of the sacrificial layers and the nanosheet layers so as to avoid forming lower source/drain portions on said sidewalls. Similarly, the second spacer 1027 may also exist on the sidewall of the fin.

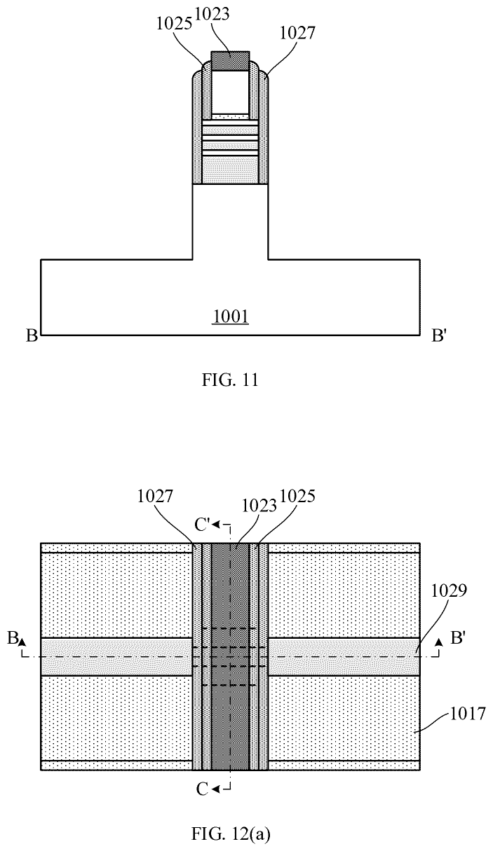

As shown in FIG. 11, the fin may be selectively etched by using the hard mask layer 1023, the first spacer 1025, and the second spacer 1027 as an etching mask through anisotropic etching such as vertical RIE. The etching may not reach a bottom of the fin (where the fin contacts a body of the substrate). As a result, a part that is self-aligned with the dummy gate and the nanosheet may be formed in the fin, and the part may form the lower channel portion of the lower layer device.

Next, lower source/drain portions and upper source/drain portions may be formed at end portions of the lower channel portion and the upper channel portion, respectively.

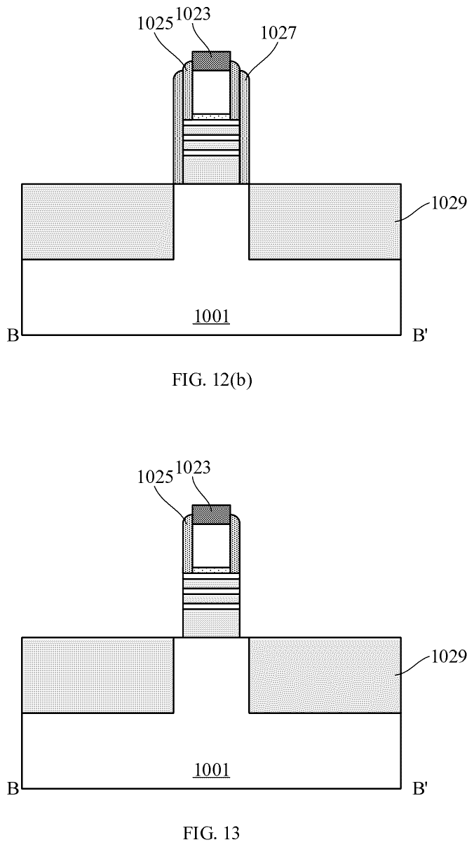

For example, as shown in FIG. 12(a) and FIG. 12(b), lower source/drain portions 1029 may be formed at two opposite ends of the lower channel portion in the first direction (e.g., a horizontal direction within a paper plane in FIG. 12(a) and FIG. 12(b)) through, for example, a selective epitaxial growth process. For example, the lower source/drain portions 1029 may contain the same material as the lower channel portion (Si), or may contain a material such as SiGe or Si: C, which is different from the lower channel portion, so as to apply appropriate stress to the lower channel portion to improve device performance. The lower source/drain portions 1029 may be in-situ doped to an appropriate conductivity type while epitaxially growing. For example, when the lower layer device is to be formed as a p-type device, the lower source/drain portions 1029 may be doped as a p-type device; and when the lower layer device is to be formed as an n-type device, the lower source/drain portions 1029 may be doped as an n-type device. Alternatively, the lower source/drain portions 1029 may be doped through other processes such as ion implantation after epitaxial growth.

It should be noted that, the lower source/drain portions 1029 may not necessarily have a planarized outer surface as shown in the drawing, but may have a surface direction determined by its crystal plane.

As mentioned above, due to the presence of the second spacer 1027, the lower source/drain portions 1029 may not be formed on the sidewall of the stack of the nanosheets and the sacrificial layers. Then, as shown in FIG. 13, the second spacer 1027 may be removed by selective etching to expose the sidewalls of the nanosheets, so as to form upper source/drain portions on the sidewalls.

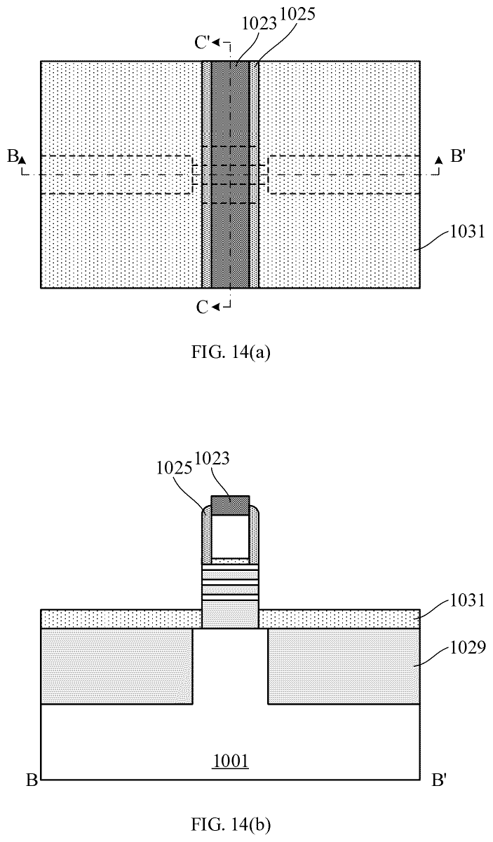

In order to achieve an electrical isolation between the lower source/drain portions and the upper source/drain portions, as shown in FIG. 14(a) and FIG. 14(b), a source/drain inter isolation layer 1031 may be formed on the lower source/drain portions 1029. The source/drain inter isolation layer 1031 may be formed by depositing an oxide, performing planarization such as CMP on the deposited oxide, and etching back the planarized oxide. A top surface of the source/drain inter isolation layer 1031 may be between top and bottom surfaces of the lowest sacrificial layer (the sacrificial layer 1003), which may expose the sidewalls of all nanosheets on the one hand, and reliably cover the source/drain portions 1029 on the other hand.

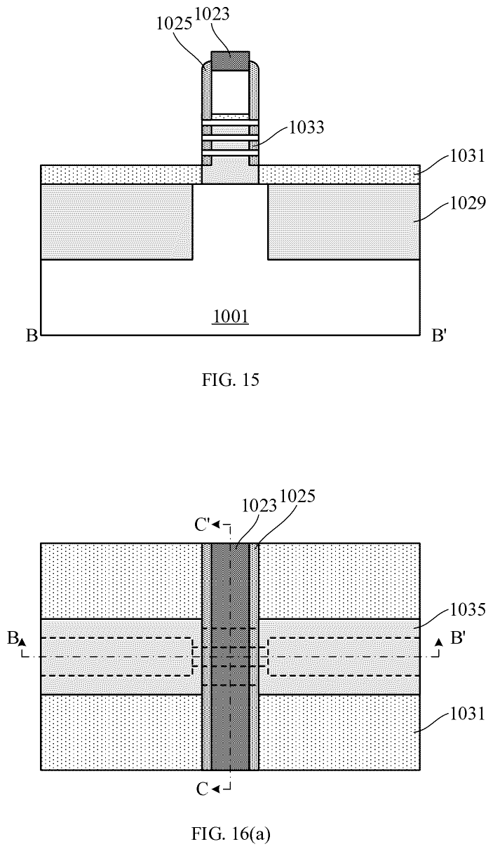

For the upper layer device, in order to achieve an electrical isolation between the sacrificial layer and the upper source/drain portions to be formed, an inner spacer may be formed. For example, as shown in FIG. 15, the exposed sidewalls of each sacrificial layer may be laterally recessed to a certain depth through selective etching, and a depth of the recess may be substantially the same as the thickness of the first spacer 1025 formed previously. In order to better control the depth of the recess, atomic layer etching (ALD) may be used. In the recess formed in this way, an inner spacer 1033 may be formed by depositing and then etching back the dielectric material. The inner spacer 1033 may contain the same material as the first spacer 1025, and may be self-aligned with the first spacer 1025.

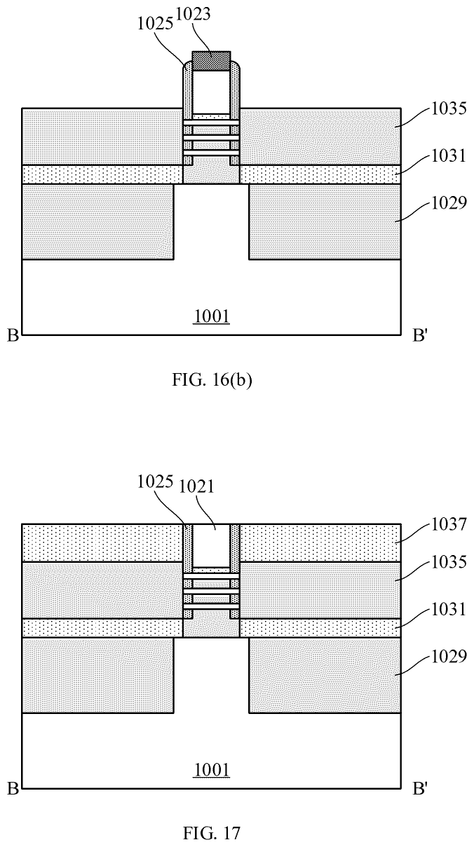

Similarly, as shown in FIG. 16(a) and FIG. 16(b), upper source/drain portions 1035 may be formed at two opposite ends of each nanosheet in the first direction (e.g., a horizontal direction within a paper plane in FIG. 16(a) and FIG. 16(b)) through, for example, a selective epitaxial growth process. For example, the upper source/drain portions 1035 may contain the same material as the upper channel portion (Si), or may contain a material such as SiGe or Si: C, which is different from the upper channel portion, so as to apply appropriate stress to the upper channel portion to improve device performance. The upper source/drain portions 1035 may be in-situ doped to a appropriate conductivity type while epitaxially growing. Alternatively, the upper source/drain portions 1035 may be doped through other processes such as ion implantation after epitaxial growth. Similarly, the upper source/drain portions 1035 may have a surface direction determined by its crystal plane.

According to embodiments of the present disclosure, the upper layer device and the lower layer device may have the same conductive type as each other, such as n-type or p-type. The upper layer device and the lower layer device may also have different conductive types from each other, such as one being n-type and the other being p-type.

It should be pointed out that although the upper source/drain portion is shown as being wider than the lower source/drain portion in the second direction in FIG. 16(a), this is only an example. As mentioned above, in order to achieve contact plugs to the upper source/drain portions and the lower source/drain portions, respectively, the lower source/drain portions may protrude relative to the upper source/drain portions in at least one of the first direction and the second direction.

Next, an alternative gate processes may be performed.

For example, as shown in FIG. 17, an interlayer dielectric layer 1037 may be formed by depositing a dielectric such as an oxide and then performing a planarization process such as CMP on the deposited dielectric. CMP may stop at the dummy gate conductor layer 1021 so as to expose the dummy gate conductor layer 1021.

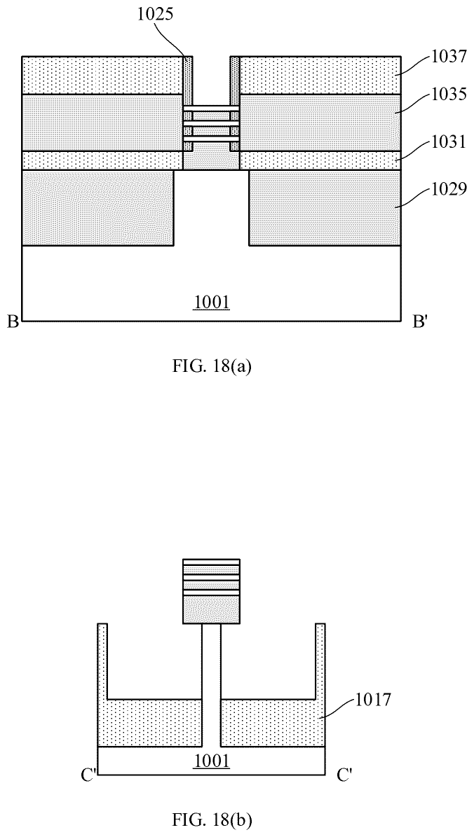

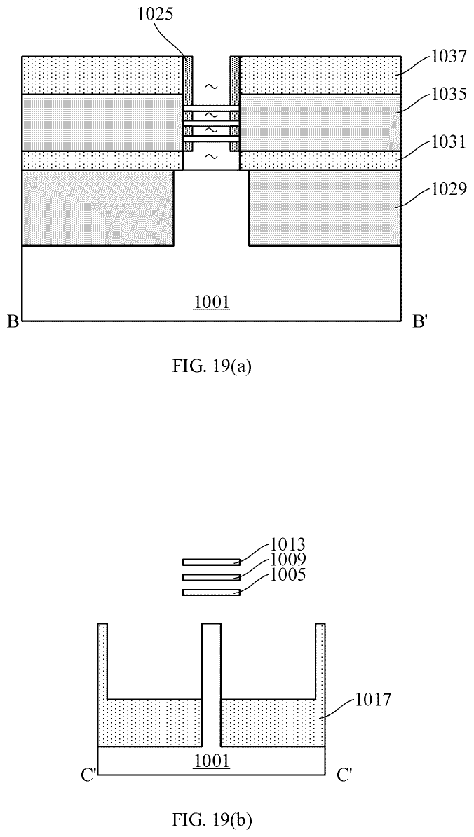

As shown in FIG. 18(a) and FIG. 18(b), the dummy gate conductor layer 1021 may be removed by selective etching, and the dummy gate dielectric layer 1019 exposed due to the removal of the dummy gate conductor layer 1021 may be removed. Then, as shown in FIG. 19(a) and FIG. 19(b), the sacrificial layers may be further removed by selective etching, so that the nanosheets are separated from each other and separated from the fin below.

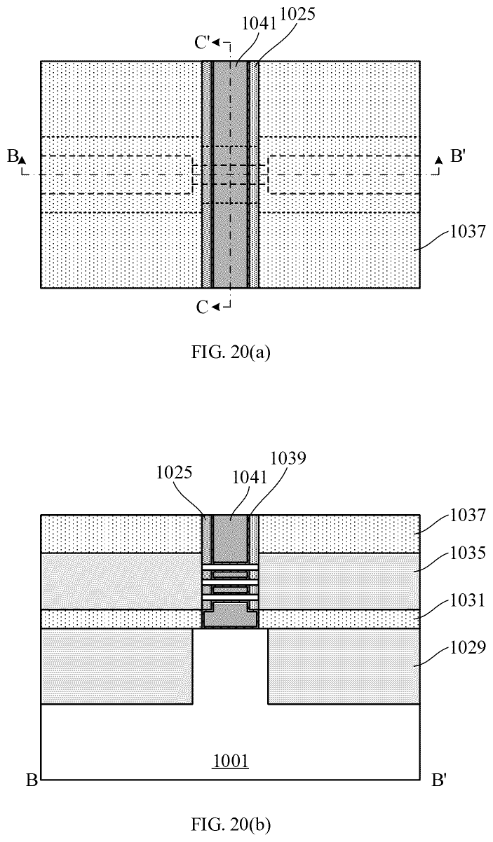

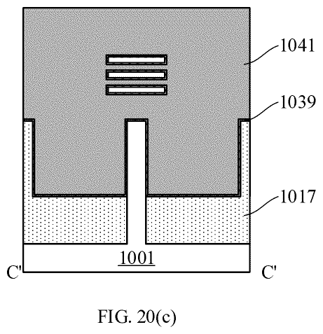

As shown in FIG. 20(a) to FIG. 20(c), the gate stack may be formed within a space defined by the first spacer 1025 and the inner spacer 1033 (and the source/drain inter isolation layer 1031). For example, a gate dielectric layer 1039 and a gate conductor layer 1041 may be formed sequentially. The gate dielectric layer 1039 may be formed in a substantially conformal manner and may contain a high k gate medium such as HfOₓ, with a thickness of about 0.3 nm to 20 nm, preferably about 0.7 nm to 2.8 nm. The gate conductor layer 1041 may contain a metal gate conductor, e.g., a metal such as Ti, Al, W, and/or a conductive metal nitride such as TiN, TaN, and the like, with a thickness of about 3 nm to 100 nm, preferably about 10 nm to 30 nm.

The gate stack may surround each nanosheet and thus form upper layer GAAFET. In addition, the gate stack may extend on the top surface and the side surface of the fin, thus forming the lower layer FinFET.

The semiconductor device according to embodiments of the present disclosure may be applied to various electronic apparatuses. For example, an integrated circuit (IC) may be formed based on such semiconductor device, and an electronic apparatus may be constructed in this way. Accordingly, the present disclosure further provides an electronic apparatus including the semiconductor device described above. The electronic apparatus may further include a display screen cooperating with the integrated circuit, a wireless transceiver cooperating with the integrated circuit, and other components. The electronic apparatus may be, for example, a smart phone, a personal computer (PC), a tablet computer, an artificial intelligence apparatus, a wearable apparatus, a portable power source, an automotive electronic apparatus, a communication apparatus, or an Internet of Things (IoT) apparatus.

According to embodiments of the present disclosure, a method of manufacturing a system on chip (SoC) is further provided. This method may include the above-mentioned method. Specifically, a variety of devices may be integrated on the chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

Embodiments of the present disclosure have been described above. However, the embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A semiconductor device, comprising:
a lower active region arranged on a substrate, wherein the lower active region comprises:
a fin extending in a first direction on the substrate, and
lower source/drain portions at two opposite ends of the fin in the first direction, respectively;
an upper active region arranged above the lower active region, wherein the upper active region comprises:
one or more nanosheets, wherein a lowest nanosheet is spaced apart from the fin in a vertical direction relative to the substrate, and
upper source/drain portions at two opposite ends of the one or more nanosheets in the first direction, respectively; and
a gate stack extending in a second direction intersecting with the first direction so as to intersect with the fin and the one or more nanosheets.

2. The semiconductor device according to claim 1, wherein the fin is self-aligned with the one or more nanosheets.

3. The semiconductor device according to claim 1, wherein the upper active region comprises a plurality of nanosheets, and each of the plurality of nanosheets is spaced apart from each other in the vertical direction and self-aligned with each other.

4. The semiconductor device according to claim 1, further comprising:
an isolation layer between the lower source/drain portions and the upper source/drain portions.

5. The semiconductor device according to claim 1, wherein the gate stack surrounds a periphery of each of the one or more nanosheets and extends on a top surface and a side surface of the fin.

6. The semiconductor device according to claim 1, wherein a width of the fin in the second direction is smaller than a width of the nanosheet in the second direction.

7. The semiconductor device according to claim 6, wherein the fin has a width of 1 nm to 50 nm in the second direction.

8. The semiconductor device according to claim 1, wherein a length of the fin in the first direction is greater than a length of the nanosheet in the first direction.

9. The semiconductor device according to claim 4, further comprising a spacer structure on sidewalls of the gate stack on two opposite sides in the first direction, wherein the spacer structure comprises:
an outer spacer extending in the second direction; and
an inner spacer extending in the second direction, between adjacent nanosheets in the one or more nanosheets and on a lower surface of the lowest nanosheet,
wherein the outer spacer, the inner spacer are located between the gate stack and the upper source/drain portion, and the isolation layer is located between the lower source/drain portion and the upper source/drain portion.

10. The semiconductor device according to claim 1, wherein the lower source/drain portion and the upper source/drain portion have a same doping type or different doping types.

11. A method of manufacturing a semiconductor device, comprising:
providing a stack of a sacrificial layer and a nanosheet alternating with each other on a substrate;
patterning the stack and an upper portion of the substrate into a stripe shape extending in a first direction, wherein the patterned upper portion of the substrate forms a fin;
thinning the fin to reduce a width of the fin in a second direction intersecting with the first direction;
forming an isolation layer on the substrate, wherein the isolation layer covers the fin;
etching the isolation layer downwardly to expose an upper portion of the fin;
forming a dummy gate on the isolation layer;
etching the stack and the fin based on the dummy gate;
forming lower source/drain portions at two opposite ends of the fin in the first direction;
forming an source/drain inter isolation layer on the lower source/drain portions;
forming upper source/drain portions at two opposite ends of the nanosheet in the first direction; and
replacing the dummy gate with a gate stack.

12. The method according to claim 11, wherein the etching the stack and the fin based on the dummy gate comprises:
forming a first spacer on a sidewall of the dummy gate in the first direction;
etching the stack by using the dummy gate and the first sidewall as a mask;
forming a second spacer on a sidewall of the stack in the first direction; and
etching the fin by using the dummy gate, the first spacer and the second spacer as a mask.

13. The method according to claim 12, wherein in a presence of the second spacer, the lower source/drain portions are formed by selective epitaxial growth, and the method further comprises: removing the second spacer after forming the lower source/drain portions.

14. The method according to claim 13, wherein the forming upper source/drain portions comprises:
selectively etching the sacrificial layer in the stack, so that an end of the sacrificial layer in the first direction is recessed transversely to form a recess, and an inner spacer is formed in the recess; and
forming the upper source/drain portions at two opposite ends of the nanosheet in the first direction by selective epitaxial growth.

15. The method according to claim 11, wherein the replacing the dummy gate with the gate stack comprises:
removing the dummy gate and the sacrificial layer, and forming a gate stack in a space generated in an inner side of the first spacer and the inner spacer due to a removal of the dummy gate and the sacrificial layer.

16. The method according to claim 11, wherein the thinned fin has a width of 1 nm to 50 nm in the second direction.

17. The method according to claim 11, wherein the downward etching on the isolation layer has an etching depth of 3 nm to 500 nm, and a width of 3 nm to 20 μm in the second direction.
